(19) United States
(12) Patent Application Publication
(10) Pub. No.: US 2026/0255697 A1
(43) Pub. Date: Aug. 27, 2026

(54) LOW SHEET RESISTANCE TRANSPARENT CONDUCTIVE ELECTRODES

(71) Applicant: Tynt Technologies, Inc., Boulder, CO (US)

(72) Inventors: Tyler James Quill, Denver, CO (US); Claudio Marchi, Broomfield, CO (US); Paige Beert, Louisville, CO (US); Tyler Steven Hernandez, Boulder, CO (US)

(73) Assignee: Tynt Technologies, Inc., Boulder, CO (US)

(21) Appl. No.: 19/532,596

(22) Filed: Feb. 6, 2026

Related U.S. Application Data
(60) Provisional application No. 63/764,161, filed on Feb. 27, 2025.

(51) Int. Cl. H10F 19/90

(52) U.S. Cl. CPC H10F 19/904

(57) ABSTRACT

The present disclosure provides transparent conductive electrodes with high optical transmission (e.g., >55% at λ=550 nm) and low sheet resistance (e.g., <5 Ω/sq). The electrodes comprise a substrate, a transparent conductive layer, and strategically arranged metallic traces that minimize optical interference patterns. The metallic traces may be arranged at angles relative to a mesh counter electrode to prevent moiré patterns while maintaining high conductivity. The disclosure also provides methods of manufacturing such electrodes and their use in reversible metal electrodeposition devices and other suitable applications.

### CROSS-REFERENCE TO RELATED APPLICATIONS

This application claims priority to U.S. Provisional Patent Application No. 63/764,161, filed February 27, 2025, the content of which is incorporated herein by reference in its entirety.

### FIELD

The present disclosure relates generally to transparent conductive electrodes and, more particularly, to transparent conductive electrodes having low sheet resistance and high optical transmission for use in reversible metal electrodeposition devices and other applications requiring both optical transparency and electrical conductivity.

### BACKGROUND

Transparent conductive electrodes are essential components in various devices, including but not limited to dynamic windows, displays, solar cells, and touch sensors. These electrodes must simultaneously possess high optical transparency to allow light transmission and high electrical conductivity to minimize resistive losses during device operation.

Conventional transparent conductive electrodes typically employ transparent conducting oxides (TCOs), such as indium tin oxide (ITO) or fluorine-doped tin oxide (FTO). While these materials provide good transparency in the visible spectrum, they often suffer from relatively high sheet resistance, which can lead to significant voltage drops across large-area devices.

Previous attempts to address this limitation have incorporated metallic grid patterns to enhance conductivity. However, when such electrodes are combined with mesh-patterned counter electrodes in devices like dynamic windows, they can produce undesirable optical interference patterns known as moiré patterns. These interference patterns significantly degrade the optical quality and aesthetics of the final device.

Therefore, there exists a need for transparent conductive electrodes that combine high optical transparency with low sheet resistance while avoiding the formation of optical interference patterns in practical device applications.

### BRIEF SUMMARY

Accordingly, the present disclosure addresses this need by providing transparent conductive electrodes with both high optical transmission and exceptionally low sheet resistance, while eliminating the formation of moiré patterns through strategic arrangement of conductive elements. The disclosed electrodes achieve optical transmission greater than 55% at 550 nm wavelength while maintaining sheet resistance below 30 Ω/sq, below 5 Ω/sq, and more preferably below 1 Ω/sq.

The disclosure utilizes highly conductive metallic traces (also known as busbars), which serve to decrease the effective sheet resistance of the overall electrode. These metallic traces provide a low resistance path for current flow parallel to the path through the transparent conductor layer of the electrode. The metallic traces have a lower resistivity than the transparent conductor, thereby reducing the effective sheet resistance of the electrode while maintaining a relatively high optical transparency.

In one aspect, the present disclosure provides a transparent conductive electrode comprising a substrate, a transparent conductive layer, and a plurality of metallic traces in electrical communication with the transparent conductive layer. The metallic traces are arranged to minimize optical interference patterns when combined with a patterned counter electrode in a device configuration. For instance, the metallic traces are arranged in a non-distortion pattern such as a non-rectilinear grid pattern relative to a mesh counter electrode.

In another aspect, the present disclosure provides methods of manufacturing such transparent conductive electrodes, including the strategic placement and patterning of metallic traces either above or below the transparent conductive layer.

The present disclosure further provides reversible metal electrodeposition (RME) devices incorporating the transparent conductive electrodes, wherein the metallic traces are arranged at angles relative to the principal directions of a mesh counter electrode to prevent the formation of moiré patterns, or patterned in a randomized pattern to minimize optical haze, scattering, and interference effects

The disclosed transparent conductive electrodes and RME devices incorporating such transparent conductive electrodes can be used in a variety of applications across different industries. For example, they can be used in dynamic windows (also known as smart windows) in architecture, which improve energy efficiency by regulating solar heat gain while maintaining aesthetics. In transportation, these electrodes enable dynamic windows in aircraft, automobiles, and marine vessels that enhance passenger comfort by controlling light and temperature without mechanical shades. For wearable applications, the technology supports dynamic eyewear that adapts to changing light conditions for both everyday use and specialized needs in sports and medical therapy. Additional implementations include privacy solutions in healthcare settings, interactive retail displays, and components for advanced display technologies. The core advantage across all applications is effective control of light transmission with uniform performance across the entire surface—a capability made possible by the low sheet resistance and high transparency of the disclosed electrodes.

### BRIEF DESCRIPTION OF THE DRAWINGS

FIG. 1 shows an exemplary schematic of the low sheet resistance electrode with busbars oriented under the transparent conductor (top) and above the transparent conductor (bottom). The figure demonstrates two alternative arrangements of the components: (1) an optically transparent conductor, (2) a conductive metal trace or a pattern or series thereof, and (3) a substrate.

FIG. 2 is an exemplary schematic showing the use of an encapsulant layer (left) on the conductive metal core of the busbar to make the conductive metal core electrochemically inert to the electrolyte and prevent chemical or electrochemical interactions or reactions. The figure also shows the use of an adhesion layer (right) to improve the adhesion of the conductive core to the transparent conductor or to decrease the contact resistance between the transparent conductor and the conductive core of the busbar. The figure further illustrates that if the busbar is under the transparent conductor (e.g., FIG. 1, top) the order of the encapsulant or adhesion layers may be adjusted.

FIG. 3 illustrates the formation of moiré patterns when combining a rectangular mesh counter electrode with a grid-like arrangement of busbar traces.

FIG. 4 illustrates the formation of moiré patterns when combining a rectangular mesh counter electrode with parallel busbar traces.

FIG. 5 illustrates the absence of moiré patterns when combining a rectangular mesh counter electrode with angled busbar traces.

### DETAILED DESCRIPTION

The following description is presented to enable a person of ordinary skill in the art to make and use the various embodiments. Descriptions of specific devices, techniques, and applications are provided only as examples. Various modifications to the examples described herein may be readily apparent to those of ordinary skill in the art, and the general principles defined herein may be applied to other examples and applications without departing from the spirit and scope of the various embodiments. Thus, the various embodiments are not intended to be limited to the examples described herein and shown but are to be accorded the scope consistent with the claims.

The present disclosure provides transparent conductive electrodes that achieve both high optical transparency and low sheet resistance through the strategic incorporation and arrangement of metallic traces. These electrodes are particularly suitable for reversible metal electrodeposition devices and other applications requiring both optical clarity and high conductivity.

### Structure and Components

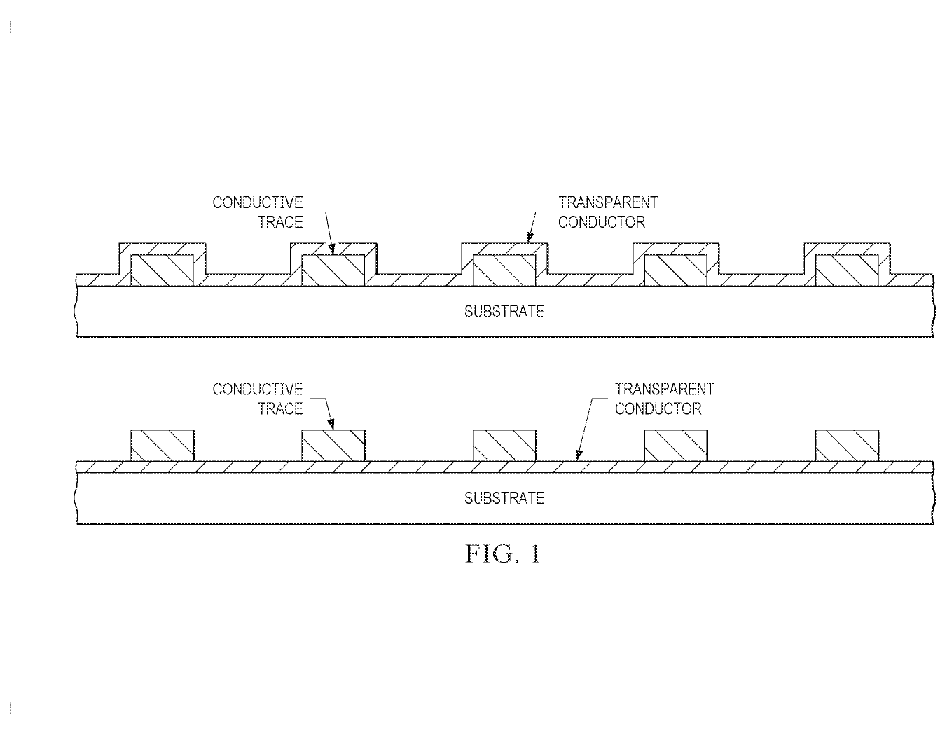

By way of example, FIG. 1 illustrates schematic cross-sectional views of two embodiments of the transparent conductive electrode, illustrating different arrangements of the metallic traces relative to the transparent conductor and substrate. Referring to FIG. 1, the transparent conductive electrode comprises three primary components: (1) an optically transparent conductor, (2) conductive metal traces (also referred to as busbars), and (3) a substrate. It is emphasized that the order and arrangement of these components is not fixed. As shown in the upper portion of FIG. 1, the metallic traces may be deposited onto the substrate, which is then coated in the transparent conductor, resulting in metallic traces under the transparent conductor. Alternatively, as shown in the lower portion of FIG. 1, the transparent conductor may be deposited on the substrate after which the metallic traces are deposited, resulting in the metallic traces on the transparent conductor.

The transparent conductor (1) may comprise various materials including, but not limited to, tin-doped indium oxide (also known as indium tin oxide, ITO), fluorine-doped tin oxide (FTO), fluorine-doped zinc oxide (FZO), aluminum-doped zinc oxide (AZO), gallium-doped zinc oxide (GZO), or indium-doped zinc oxide (IZO). The transparent conductor may be produced or deposited on the substrate via physical vapor deposition such as sputtering or electron-beam evaporation, chemical vapor deposition or plasma enhanced chemical vapor deposition, or other methods.

The conductive metal traces (2) consist of a metal core which may or may not be encapsulated. The metal core may comprise copper, aluminum, silver, gold, platinum, palladium, titanium, chromium, nickel, molybdenum, or combinations thereof. For example, the conductive traces may consist of layers of the aforementioned materials for the goal of reducing contact resistance between the transparent conductor and the conductive trace, improving adhesion, or providing corrosion resistance.

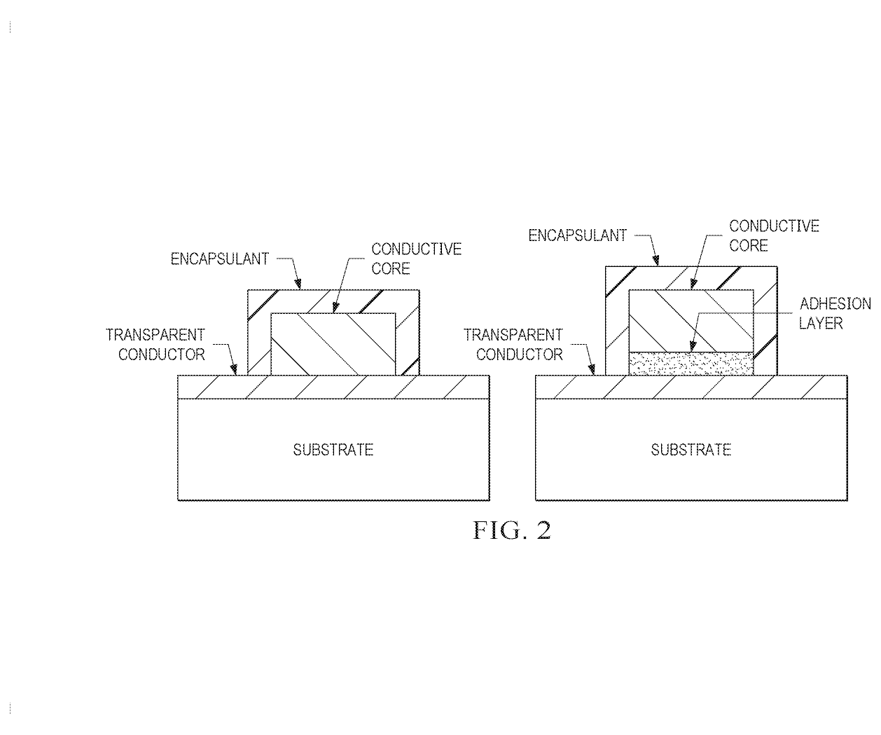

Referring to FIG. 2, the conductive trace may be coated, encapsulated, or patterned with a dielectric material (an insulator) at various interfaces. As shown in the left portion of FIG. 2, an encapsulant layer may be applied to make the conductive metal core electrochemically inert to the electrolyte and prevent chemical or electrochemical interactions or reactions. As shown in the right portion of FIG. 2, an adhesion layer may be incorporated to improve the adhesion of the conductive core to the transparent conductor or to decrease the contact resistance between the transparent conductor and the conductive core. For example, a thin layer of Aluminum can be deposited between the silver trace and the transparent conductor to enhance adhesion and/or limit contact resistance thereby lowering the overall sheet resistance. Another example includes the addition of a chromium layer to enhance adhesion between the conductive trace and the substrate.

The dielectric material used for encapsulation may consist of transition metal oxides (such as Aluminum Oxide, Copper Oxide, Silicon Oxide, Molybdenum Oxide, Silver Oxide, Chromium Oxide, Titanium Oxide), transition metal fluorides, organic materials such as small molecule dielectrics, polymeric dielectrics, or photoresist. Specific examples include parylene, poly(styrene), CYTOP, SU-8 photoresist, poly(methyl-methacrylate), poly(siloxane), or derivatives thereof.

The conductive metal core and/or any coating or encapsulant layer may be patterned using but not limited to shadow masking, photolithography, gravure printing, nanoimprint lithography and may be deposited using but not limited to physical vapor deposition (including thermal evaporation, electron-beam evaporation, or sputtering), chemical vapor deposition (CVD), atomic layer deposition (ALD), molecular beam epitaxy (MBE), spin coating, electrodeposition, annealing, plasma treatment, or ozone treatment.

Additionally, the conductive metal traces may consist of sintered, joined, or contacting particles of the metal. These particles can be dispersed in a matrix to form an ink, paste, or the like which allows the metal traces to be screen printed, 3D printed, inkjet-printed, slot die coated, or deposited via other methods.

### Dimensional Considerations

The metallic traces are designed with specific dimensional constraints to optimize both optical and electrical performance. In preferred embodiments, the traces have a height less than 5 μm and a width less than 15 μm. These dimensions render the traces nearly imperceptible to the human eye while maintaining sufficient cross-sectional area for electrical conduction.

### Pattern Design and Moiré Prevention

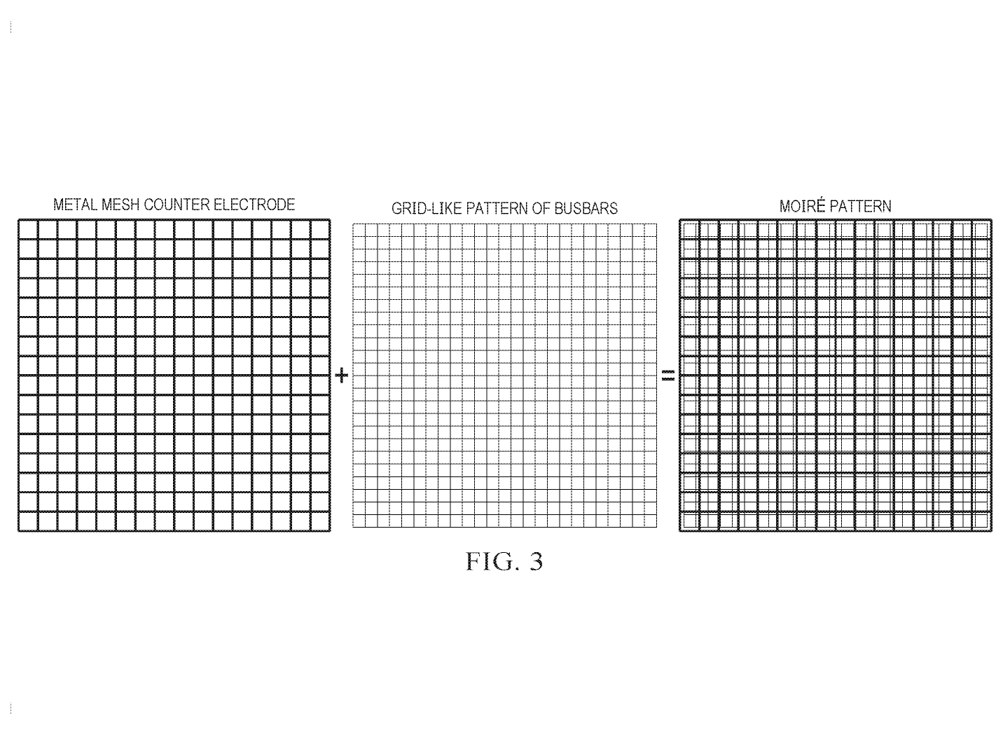

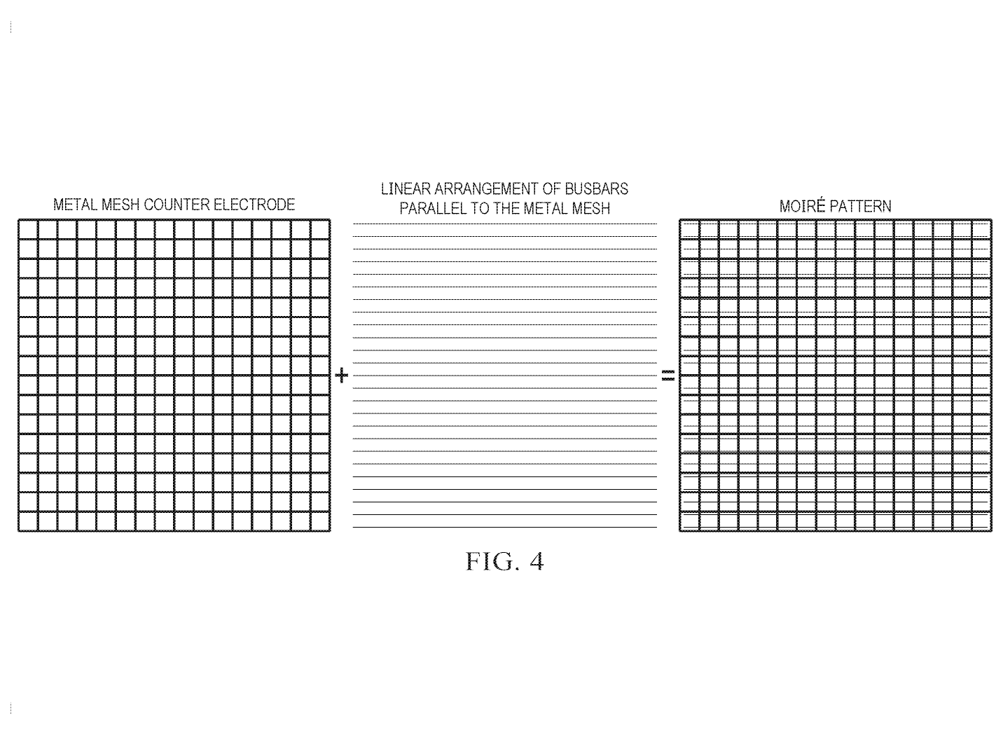

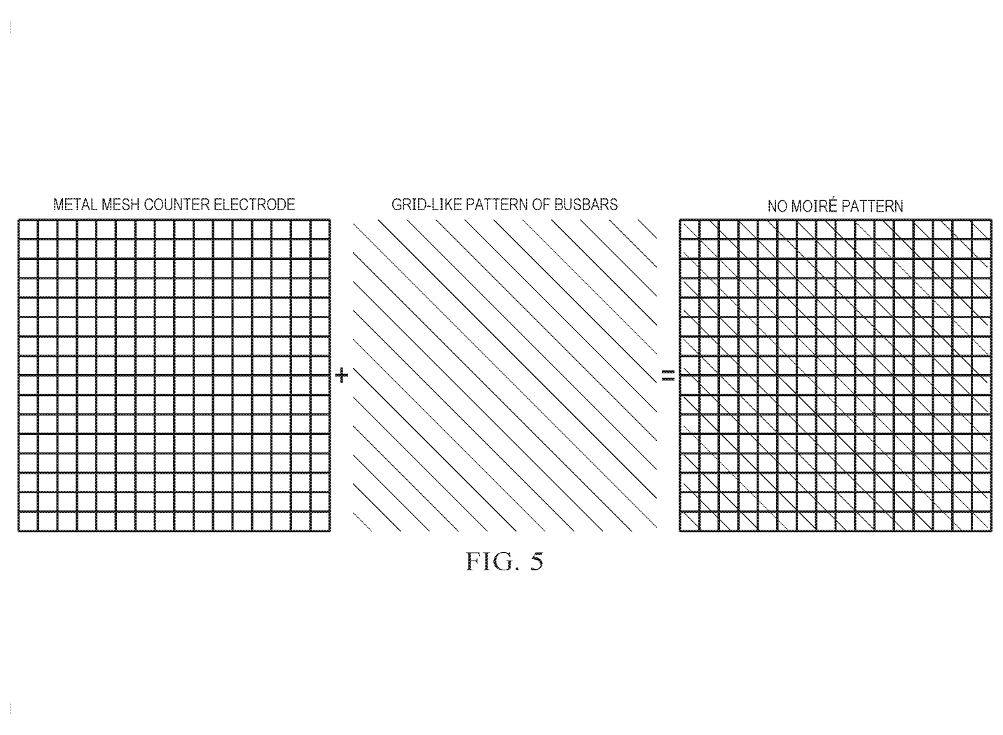

A key aspect of the present disclosure lies in the strategic arrangement of metallic traces to prevent optical interference, known as moiré patterns. As shown in FIG. 3 and FIG. 4, conventional grid patterns or parallel line arrangements can produce undesirable moiré patterns when combined with mesh counter electrodes. In contrast, FIG. 5 demonstrates how angling the traces relative to the principal directions of the mesh counter electrode eliminates these interference patterns.

While a number of exemplary aspects and embodiments have been discussed above, those of skill in the art may recognize certain modifications, permutations, additions and sub-combinations thereof. It is therefore intended that the following appended claims and claims hereafter introduced are interpreted to include all such modifications, permutations, additions and sub-combinations as are within their true spirit and scope.

### EXAMPLES

The following examples are offered to illustrate provided embodiments and are not intended to limit the scope of the present disclosure.

### Example 1: Fabrication of Low Sheet Resistance Electrode with Underlayer

Referring to the configuration shown in the upper portion of FIG. 1, a transparent conductive electrode is prepared by first depositing silver traces on a glass substrate through a shadow mask using thermal evaporation. The traces are 2 μm in height and 8 μm in width, arranged at a 45° angle relative to the substrate edges, with 500 μm spacing between traces. An ITO layer is then deposited over the silver traces using RF magnetron sputtering to a thickness of 150 nm.

As illustrated in FIG. 2 (right), a chromium adhesion layer of 5 nm thickness is deposited prior to the silver trace deposition to improve adhesion to the substrate. The resulting electrode structure matches the schematic diagram showing the adhesion layer configuration.

The completed electrode exhibits an optical transmission of 85% at 550 nm and a sheet resistance of 0.8 Ω/sq.

### Example 2: Fabrication of Low Sheet Resistance Electrode with Overlayer

Following the configuration shown in the lower portion of FIG. 1, an alternative electrode structure is fabricated by first depositing a 150 nm ITO layer on a glass substrate. Silver traces are then deposited on top of the ITO layer using electron beam evaporation through a shadow mask. The traces have the same dimensions as in Example 1.

As shown in FIG. 2 (left), a dielectric encapsulation layer of aluminum oxide (10 nm) is deposited over the silver traces using atomic layer deposition to protect them from environmental degradation and prevent unwanted electrochemical reactions.

### Example 3 : Integration with RME Device and Moiré Pattern Prevention

The transparent conductive electrodes from Examples 1 and 2 are incorporated into reversible metal electrodeposition (RME) devices as working electrodes. The counter electrode comprises a silver mesh pattern with 50 μm line spacing, as illustrated in FIG. 3 (left panel).

When conventional grid-like patterns are used for the working electrode, as shown in FIG. 3 (center and right panels), prominent moiré patterns emerge. Similarly, FIG. 4 demonstrates that parallel alignment of the traces with the mesh pattern also results in interference patterns.

However, when the traces are arranged at a 45° angle relative to the mesh pattern, as illustrated in FIG. 5, no moiré patterns are observed. The completed device switches between clear and colored states with a response time of less than 3 minutes for a 1 m² panel, enabled by the low sheet resistance of the transparent conductive electrode.

Taken together, these examples demonstrate successful implementation of transparent conductive electrodes that simultaneously achieve high optical transmission (>85% at 550 nm) and low sheet resistance (<1 Ω/sq) through strategic placement and orientation of metallic traces. The examples further demonstrate the versatility of the fabrication process, allowing for both underlayer and overlayer configurations, as well as the incorporation of functional adhesion and encapsulation layers. Most importantly, these examples validate the effectiveness of the angled trace arrangement in preventing moiré pattern formation when combined with mesh counter electrodes, thereby solving a significant challenge in the implementation of high-performance transparent electrodes in practical devices.

What is claimed is:

1. A transparent conductive electrode comprising:
a substrate;
a transparent conductive layer; and
a plurality of metallic traces in electrical communication with the transparent conductive layer,
wherein the metallic traces are arranged to minimize optical interference patterns.

2. The transparent conductive electrode of claim 1, wherein the transparent conductive layer has an optical transmission greater than 55% at 550 nm wavelength.

3. The transparent conductive electrode of claim 1, wherein the transparent conductive electrode has an effective sheet resistance less than 30 ohm/square.

4. The transparent conductive electrode of claim 3, wherein the sheet resistance is less than 1 ohm/square.

5. The transparent conductive electrode of claim 1, wherein the metallic traces are arranged in a non-rectilinear grid pattern relative to a mesh counter electrode.

6. The transparent conductive electrode of claim 5, wherein the metallic traces are arranged at an angle relative to principal directions of the mesh counter electrode to prevent formation of moiré patterns.

7. The transparent conductive electrode of claim 1, wherein the metallic traces are disposed between the substrate and the transparent conductive layer, and/or disposed on a surface of the transparent conductive layer opposite the substrate.

8. The transparent conductive electrode of claim 1, wherein the metallic traces comprise a metal core selected from the group consisting of copper, aluminum, silver, gold, platinum, palladium, titanium, chromium, nickel, molybdenum, and combinations thereof.

9. The transparent conductive electrode of claim 1, wherein the metallic traces have a height less than 5 micrometers and a width less than 15 micrometers.

10. The transparent conductive electrode of claim 1, wherein the metallic traces comprise an adhesion layer and a metal core.

11. The transparent conductive electrode of claim 1, wherein the metallic traces comprise an encapsulation layer comprising a dielectric material.

12. A method of manufacturing a transparent conductive electrode, the method comprising:
providing a substrate;
forming a transparent conductive layer; and
forming a plurality of metallic traces in electrical communication with the transparent conductive layer.

13. The method of claim 12, wherein forming a plurality of metallic traces comprises arranging the plurality of metallic traces in a pattern that minimizes optical interference patterns.

14. The method of claim 12, wherein forming the metallic traces comprises: depositing a metal core layer; depositing at least one adhesion layer; and patterning the metal core layer and adhesion layer.

15. The method of claim 12, further comprising depositing a dielectric encapsulation layer over the metallic traces.

16. The method of claim 12, wherein forming a plurality of metallic traces comprises arranging the plurality of metallic traces at an angle relative to principal directions of a mesh counter electrode to prevent formation of moiré patterns.

17. A reversible metal electrodeposition device comprising:
a first electrode comprising a transparent conductive layer and a plurality of metallic traces;
a counter electrode; and
a reversible metal electrodeposition electrolyte between the first electrode and the counter electrode.

18. The device of claim 17, wherein the counter electrode comprises a metallic mesh pattern, and wherein the metallic traces are arranged to minimize optical interference patterns with the metallic mesh pattern.

19. The device of claim 17, wherein the metallic traces have dimensions that render them substantially undetectable to human vision while providing sufficient conductivity to achieve a sheet resistance less than 30 ohm/square.

20. The device of claim 17, wherein the device is selected from the group consisting of a glass, a window, a mirror, a panel, a ceiling, an eyewear, a privacy screen, and a display.
